(19) United States
(12) Patent Application Publication
(10) Pub. No.: US 2010/0319748 A1
(43) Pub. Date: Dec. 23, 2010

(54) THERMOPILE WIRE, WINDING SUPPORT, AND METHOD AND MACHINE FOR THE PRODUCTION OF A THERMOELECTRIC GENERATOR

(75) Inventor: Ullrich Hetzler, Dillenburg-Oberscheld (DE)

Correspondence Address: CAESAR, RIVISE, BERNSTEIN,;COHEN & POKOTILOW, LTD., 11TH FLOOR, SEVEN PENN CENTER, 1635 MARKET STREET, PHILADELPHIA, PA, 19103-2212, US

(73) Assignee: ISABELLENHUETTE HEUSLER GMBH & CO. KG, Dillenburg (DE)

(21) Appl. No.: 12/528,387

(22) PCT Filed: Feb. 20, 2008
(86) PCT No.: PCT/EP2008/001329

§ 371 Date: Aug. 24, 2009

(30) Foreign Application Priority Data
Feb. 26, 2007 (DE) 102007009221.2

(51) Int. Cl. H01L 35/28; H01L 35/34; H01L 35/02; B65H 54/00

(52) U.S. Cl. 136/211; 136/226; 136/242; 242/430; 136/201

(57) ABSTRACT

The invention relates to a thermopile wire (1), a winding support for such a thermopile wire, as well as a method and a machine (11) for producing a thermoelectric generator including a thermopile wire (1). The invention takes into account that the effective winding diameter changes from one winding layer of the thermopile wire (1) to the next when the thermopile wire (1) is wound.

The invention relates to a thermopile wire and a winding support for a thermopile wire. Furthermore, the invention relates to a method and machine for the production of a thermoelectric generator with a thermopile wire.

From the utility model document DE 20 2006 003 595 U1 a thermopile wire is known which has numerous thermocouples disposed one behind the other and electrically connected in series and which can be used for the production of a thermoelectric generator (“thermoconverter”) in that the thermopile wire is wound on a winding support in such a way that the hot connection points on the one hand and the cold connection points on the other are disposed on opposite sides of the winding support. In the case of a temperature difference between the opposite sides of the winding support, the wound thermopile wire then produces a corresponding thermoelectric voltage.

The problem arises therein that when the winding support is wound with a plurality of winding layers of the thermopile wire lying one above the other, the effective winding perimeter changes from one winding layer to the next winding layer. When the individual thermocouples are of a uniform length in the thermopile wire, this in turn leads to the situation where the hot and cold connection points of the thermopile wire in the individual winding layers are offset with respect to the preset position. However, it is desirable that the hot connection points on the one hand and the cold connection points on the other should lie precisely opposite each other with no incorrect alignment.

In relation to the prior art, further reference is made to U.S. Pat. No. 3,357,866 A, U.S. Pat. No. 3,700,503 A, DD 103 763 A1, U.S. Pat. No. 3,150,844 A, GB 819 273 A, DE 195 29 725 A1, DE 43 35 089 A1, DE 17 74 229 B2, DE 34 20 294 A1. However, these cited documents relate for the most part to thermoelectric generators with a single-layer winding of the thermopile wire so that the winding diameter of the thermopile wire is constant. In any case, a targeted adaptation of the length of the individual thermocouples or thermocouple legs is not known from these cited documents.

The invention is thus based on the task of solving the problem of incorrect positioning of the hot and cold connection points of the thermopile wire in the successive winding layers.

This task is solved by a thermopile wire in accordance with the invention, a corresponding winding support and by a method and a machine for the production of a thermoelectric generator in accordance with the independent claims.

The invention firstly relates to a thermopile wire which largely corresponds to a conventional thermopile wire as described e.g. in the utility model document DE 20 2006 003 595 U1. In order to avoid repetition reference is therefore made to this utility model document in relation to the structure and to the production of a thermopile wire in accordance with the invention, the content of which document is to be entirely included in the present application.

The thermopile wire in accordance with the invention is distinguished with respect to the above-mentioned conventional thermopile wire in that the length of the individual thermocouples and/or the length of the individual thermocouple legs is not constant along the thermopile wire. It is rather the case that the invention makes provision for the length of the individual thermocouples and/or the length of the individual thermocouple legs to increase monotonously or decrease monotonously along the thermopile wire. This change in length of the individual thermocouples or thermocouple legs makes it possible for the hot and cold connection points to lie precisely at the intended position in the wound state in spite of the change in the effective winding diameter from one winding layer to the next winding layer.

In one variant of the thermopile wire in accordance with the invention all directly successive thermocouples and/or thermocouple legs each have a given difference in length. This means that each thermocouple or each thermocouple leg has a given difference in length with respect to the thermocouple or thermocouple leg directly preceding it. This variant is particularly suitable when no windings lie next to each other on the winding support so that each winding forms a new winding layer.

In contrast, in another variant of a thermopile wire in accordance with the invention the directly successive thermocouples and/or thermocouple legs have a given difference in length only in the case of every n^{th} thermocouple and otherwise are of the same length. The thermocouples are thus divided into successive groups, wherein the thermocouples and/or thermocouple legs in the individual groups each have the same length, while the thermocouples and/or thermocouple legs in the directly successive groups have a given difference in length. This variant is useful in particular where the thermopile wire in accordance with the invention is to be wound on a winding support, wherein in the wound state a plurality of windings lie next to each other so that the effective winding perimeter changes only in the case of every n^{th} winding.

The difference in length between the successive thermocouples is thus preferably substantially equal to the perimeter of the thermopile wire in order to compensate for the change in the effective winding perimeter from one winding layer to the next winding layer.

Furthermore, the invention relates to a winding support for winding with a conventional thermopile wire, as described e.g. in the utility model document DE 20 2006 003 595 U1. In order to be wound with the thermopile wire the winding support in accordance with the invention has a winding region with a given winding perimeter, wherein the winding perimeter is adapted to the length of the individual thermocouples in the thermopile wire in such a way that the hot connection points of the thermocouples on the one hand and the cold connection points of the thermocouples on the other are disposed substantially on opposite sides of the winding support in the wound state in order to form a thermoelectric generator. However, the problem also arises in this case that the effective winding perimeter of the winding region increases from one winding layer to the next winding layer, which can lead to slightly incorrect positioning of the hot and cold connection points.

The winding support in accordance with the invention therefore has, in addition to the winding region, a compensation region which serves to receive at least one compensation winding of the thermopile wire, wherein the compensation region has a different winding perimeter than the winding region. For example the compensation region can have a smaller winding perimeter than the winding region so that the smaller perimeter of the compensation winding effects a positional correction for the hot and cold connection points.

In one exemplified embodiment of the invention the compensation region consists substantially of an annular groove which is disposed at one end or at both ends of the winding region and can receive one or more compensation windings.

It should be mentioned at this point that the winding support does not necessarily have to be of a cylindrical form as known from the prior art. Within the scope of the invention it is rather the case that the possibility also exists of the winding support being formed differently. For example the winding body can have an oval, rectangular or square winding cross-section.

Furthermore, the invention not only relates to the above-described thermopile wire in accordance with the invention and to the above-described winding support in accordance with the invention but also to a thermoelectric generator with a thermopile wire in accordance with the invention or a winding support in accordance with the invention.

Furthermore, the invention relates to a production method for a thermoelectric generator, in which a thermopile wire with a plurality of thermocouples disposed one behind the other and each having two thermocouple legs and hot connection points and cold connection points is provided. This thermopile wire can be a conventional thermopile wire as described e.g. in the utility model document DE 20 2006 003 595 U1. However, the production method in accordance with the invention is based on the above-described thermopile wire in accordance with the invention, in which the length of the individual thermocouples or thermocouple legs monotonously increases or monotonously decreases along the thermopile wire.

Furthermore, the production method in accordance with the invention makes provision that the thermopile wire is wound in a conventional manner on a winding support so that the hot connection points on the one hand and the cold connection points on the other lie on opposite sides of the winding support. The winding of the thermopile wire on the winding support is also described in the above-mentioned utility model document DE 20 2006 003 595 U1 so that the content of this utility model document is to be entirely included in the present application.

The production method in accordance with the invention additionally makes provision that the actual position of the hot connection points and/or of the cold connection points of the thermocouples in the thermopile wire is detected during production, which can be effected, e.g. by an optical sensor.

Within the scope of the production method in accordance with the invention the desired-actual deviation between the determined actual position of the connection points and a given desired position of the connection points is then determined.

In dependence upon the desired-actual deviation thus determined the thermopile wire is then extended in the longitudinal direction before and/or during winding onto the winding support so that in the wound state the hot connection points on the one hand and the cold connection points on the other are disposed as precisely as possible at the intended positions on opposite sides of the winding support.

An advantageous feature of the production method in accordance with the invention is also the possibility of continuous production of the thermopile wire, as described e.g. in DE 20 2006 003 595 U1, so that the content of this utility model document is to be entirely included in the present description. During production of the thermopile wire in accordance with the invention a quasi-endless support element (e.g. a wire) can be unwound from a winding body and then coated in the unwound state in order to produce the individual thermocouples of different lengths. The thermopile wire produced in this way can then be wound onto a winding body and transported and stored in the wound state. Furthermore, the thermopile wire produced in this way can be divided into a plurality of thermopile wires which are then each wound individually onto winding bodies. When dividing a thermopile wire in accordance with the invention into a plurality of thermopile wires it is useful if the transition can in each case be registered in the production line concerned. The registering of the position of the thermopile wire is also useful if, in a production line, a new winding body is to be wound with a new thermopile wire since the precise positioning of the hot and cold connection points is important then.

The structurally-imposed change in length of the individual thermocouples in the thermopile wire in accordance with the invention thus effects a rough correction in the position of the hot and cold connection points, while the extension of the thermopile wire effects a fine correction.

Finally, the invention also relates to a machine for carrying out the production method described above.

Other advantageous developments of the invention are characterized in the subclaims or are explained in more detail hereinunder together with the description of the preferred exemplified embodiments of the invention with the aid of the figures in which:

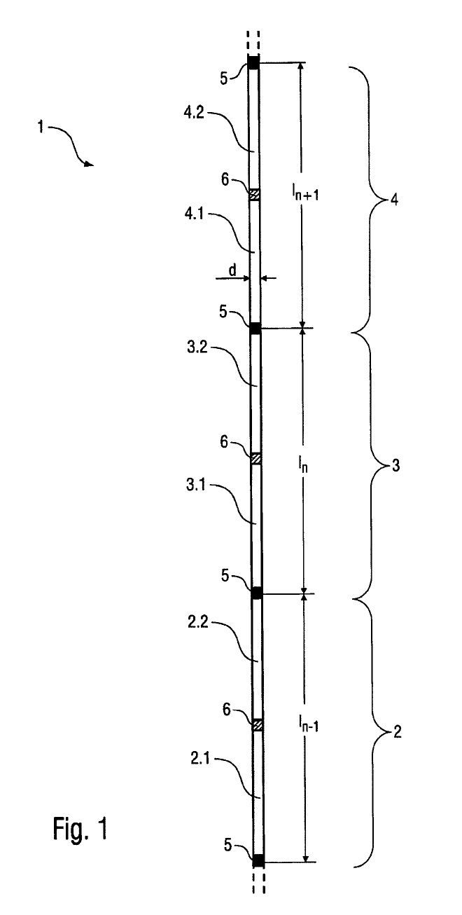

FIG. 1 shows a side view of a part of a thermopile wire in accordance with the invention,

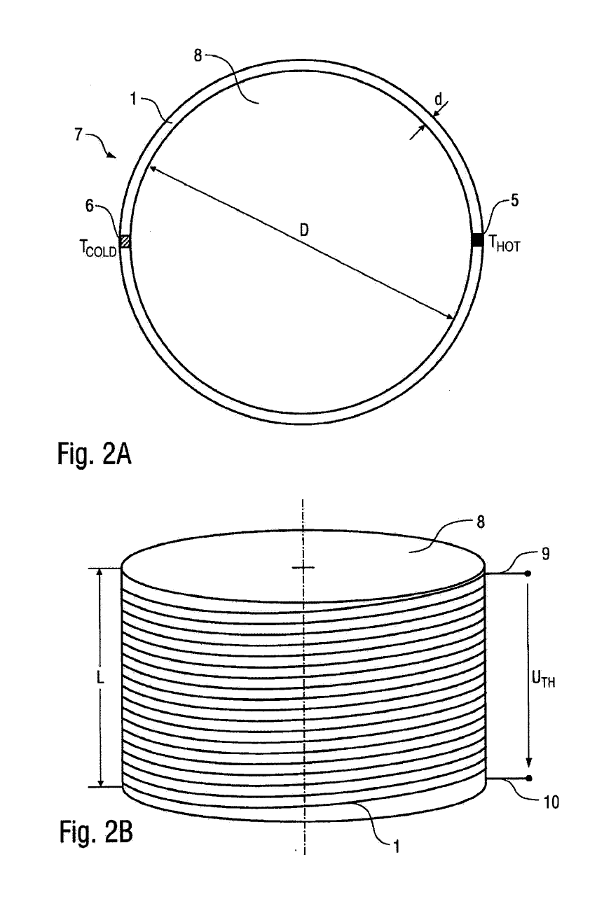

FIG. 2A shows a plan view of a thermoelectric generator,

FIG. 2B shows a perspective view of the thermoelectric generator in accordance with FIG. 2A,

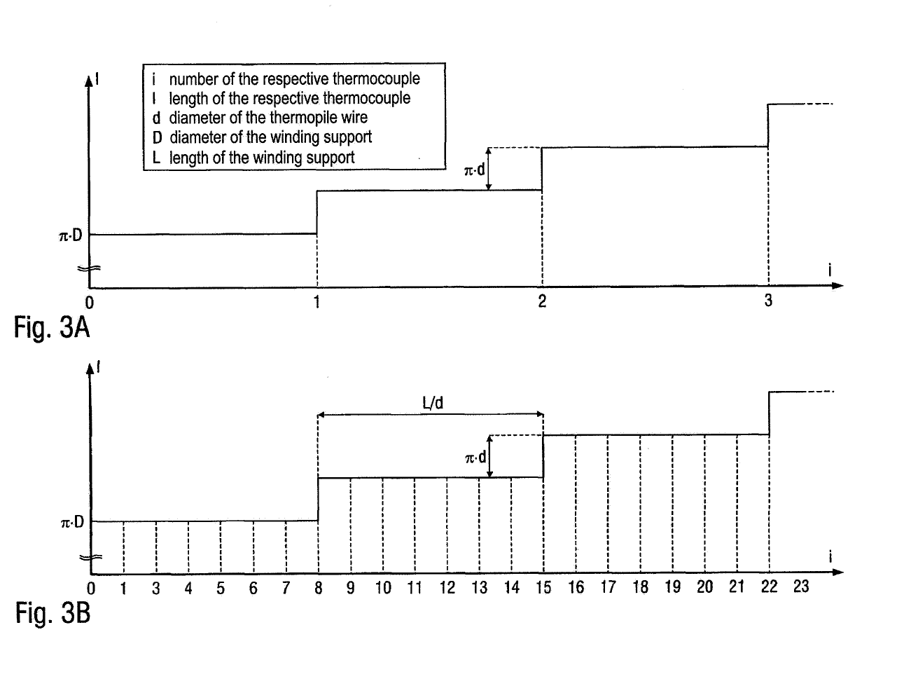

FIG. 3A shows a diagram which illustrates the change in length of the individual thermocouples along the thermopile wire,

FIG. 3B shows a corresponding diagram for another exemplified embodiment of a thermopile wire in accordance with the invention,

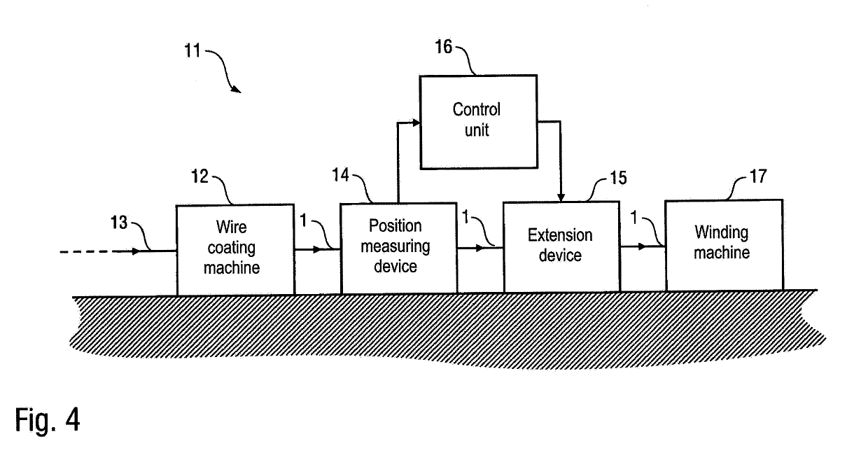

FIG. 4 shows a greatly simplified schematic view of a machine in accordance with the invention for the production of a thermoelectric generator,

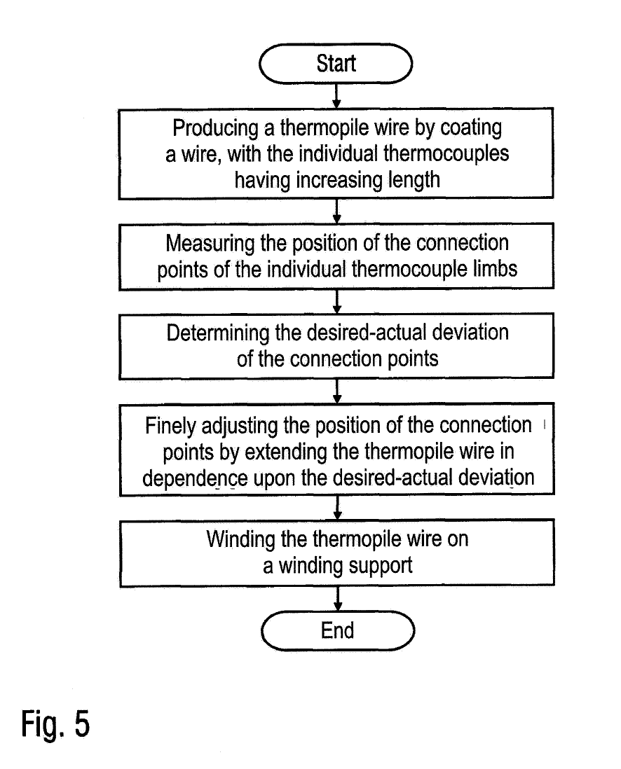

FIG. 5 shows the production method in accordance with the invention in the form of a flow diagram,

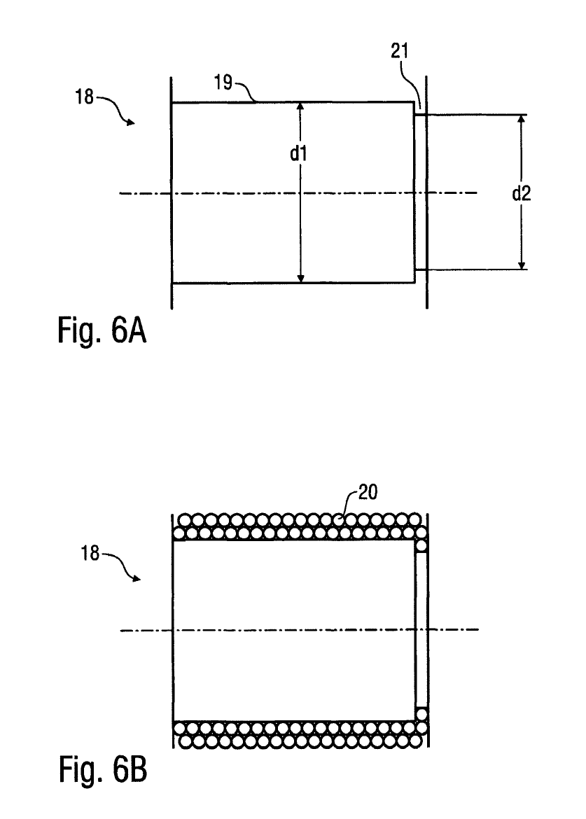

FIG. 6A shows a side view of a winding support in accordance with the invention and

FIG. 6B shows the winding support in accordance with FIG. 6A with two winding layers of a thermopile wire.

FIG. 1 shows a part of a thermopile wire 1 in accordance with the invention with a plurality of thermocouples 2, 3, 4 which are disposed one behind the other and are electrically connected in series, wherein the individual thermocouples 2-4 each have two thermocouple legs 2.1, 2.2, 3.1, 3.2, 4.1, 4.2.

The individual thermocouple legs 2.1, 2.2, 3.1, 3.2, 4.1, 4.2 are connected to each other in each case by hot connection points 5 and cold connection points 6. During production of a thermoelectric generator from the thermopile wire 1 the hot connection points 5 are then subjected to a higher temperature than the cold connection points 6, whereupon the thermopile wire 1 produces a corresponding thermoelectric voltage.

The detailed structure and production method of the thermopile wire 1 is extensively described in the utility model document DE 20 2006 003 595 U1 so that the content of this utility model document is to be entirely included in the present application in relation to the structure and production of the thermopile wire 1.

The particular feature in accordance with the invention of the thermopile wire 1 in comparison to conventional thermopile wires consists of the fact that the individual thermocouples 2, 3, 4 have different lengths lₙ₊₁, lₙ, lₙ₋₁, wherein the length of the individual thermocouples 2-4 increases monotonously in the longitudinal direction of the thermopile wire 1, i.e. lₙ₋₁≦lₙ≦lₙ₊₁, wherein there is a difference in length at least in the case of two successive thermocouples. In the wound state this change in length of the individual thermocouples 2-4 along the thermopile wire 1 should compensate for the change in the effective winding diameter from one winding layer to the next winding layer.

FIGS. 2A and 2B show a thermoelectric generator in accordance with the invention with a cylindrical winding support 8 which is wound with the thermopile wire 1 in accordance with the invention. The diameter D of the winding support 8 is thus matched to the length lₙ₋₁1, lₙ, lₙ₊₁ of the individual thermocouples 2-4 and to the diameter d of the thermopile wire 1 in such a way that the hot connection points 5 on the one hand and the cold connection points 6 on the other lie as precisely as possible on opposite sides of the winding support 8.

The winding support 8 has a winding length L so that on the circumferential surface of the winding support 8 a number m=L/d of windings of the thermopile wire 1 can be positioned next to each other and each form a common winding layer. In contrast, in the next winding layer the effective winding perimeter of the winding support 8 changes owing to the winding layer lying below it so that with n=m+1 the n^{th} thermocouple 2 has a greater length lₙ than the preceding thermocouples 3, 4. The difference in length between the (n+1)^{th} thermocouple 2 and the n^{th} thermocouple 3 corresponds to the perimeter of the thermopile wire 1.

In this way it is achieved that the hot connection points 5 on the one hand and the cold connection points 6 on the other also lie precisely at opposite points of the winding support 8 in the upper winding layers.

Furthermore, it should be stated that the thermoelectric generator 7 has two voltage taps 9, 10 which are connected to the opposite ends of the thermopile wire 1 and output a corresponding thermoelectric voltage U_{TH}.

FIGS. 3A and 3B show different possible progressions of the length lᵢ of the successive thermocouples in a thermopile wire in accordance with the invention.

In the exemplified embodiment in accordance with FIG. 3A the length lᵢ of the successive thermocouples increases in each case from one thermocouple to the next thermocouple by the amount U=π·d of the thermopile wire. This change in length is suitable in particular for strip-like thermopile wires in which each winding of the thermopile wire belongs to a new winding layer.

In contrast, in the exemplified embodiment in accordance with FIG. 3B only every seventh thermocouple has a corresponding change in length with respect to the preceding thermocouple. This progression in the length of the individual thermocouples is suitable in particular for the winding of winding supports in which seven windings of the thermopile wire each lie next to each other and form a common winding layer.

FIG. 4 shows a roughly simplified illustration of a machine 11 in accordance with the invention for producing the thermoelectric generator 7 in accordance with FIGS. 2A and 2B.

Firstly, the machine in accordance with the invention has a conventional wire coating machine 12 which is supplied with a conventional wire 13 as a starting product. The wire coating machine 12 then produces the thermopile wire 1, wherein the wire 13 forms the support element of the thermopile wire 1, as described e.g. in the utility model document DE 20 2006 003 595 U1. During production of the thermopile wire 1 the wire coating machine 12 can apply coatings of insulating material or conductive material to the wire 13 or partially remove coatings from the wire 13, as described in the utility model document DE 20 2006 003 595 U1, so that the content of this utility model document with respect to the production of the thermopile wire 1 in accordance with the invention is to be entirely included.

The thermopile wire 1 is then supplied to a position measuring device 14 which determines the position of the hot connection points 5 and the cold connection points 6 with a suitable sensor. The sensor for registering the position can be e.g. an optical sensor but other types of sensor can also be used within the scope of the invention.

The thermopile wire 1 measured in this way is then supplied to an extension device 15 which extends the thermopile wire 1 in the longitudinal direction in a variable manner. The extension of the thermopile wire 1 is controlled by a control unit 16 in dependence upon the previously determined position of the hot connection points 5 and of the cold connection points 6 in such a way that the connection points 5, 6 lie precisely at the intended position in the finished thermoelectric generator.

The thermopile wire 1 extended in this way is then supplied to a conventional winding machine 17 which winds the thermopile wire 1 onto the winding support 8.

The structurally-provided change in length of the individual thermocouples 2-4 in the thermopile wire 1 thus effects a rough correction of the position of the connection points 5, 6 in the successive winding layers.

In contrast, the extension of the thermopile wire 1 by the extension device 15 effects an additional fine correction of the position of the connection points 5, 6.

Finally, FIG. 5 shows the production method of the machine 11 in accordance with FIG. 4 in the form of a flow diagram, as already results from the preceding description.

FIGS. 6A and 6B show another exemplified embodiment of a thermoelectric generator 18 in accordance with the invention having a winding support 19 which can be wound with a conventional thermopile wire 20 as known e.g. by the utility model document DE 20 2006 003 595 U1. The thermopile wire 20 thus has a uniform length for the individual thermocouples.

The change in the effective winding diameter in the winding layers which lie on top of each other is in this case compensated for by the fact that at one end of the winding support 19 an annular groove 21 is disposed which receives one or more windings of the thermopile wire 20 and has a winding diameter d2 which is smaller than the winding diameter d1 of the rest of the winding support 19. The windings of the thermopile wire 20 in the annular groove 21 thus form compensation windings for the enlarged winding perimeter in the respectively successive winding layer.

The invention is not limited to the preferred exemplified embodiments described above but it is much rather the case that a plurality of variants and modifications are possible which also make use of the inventive idea and therefore fall within the range of protection.

### REFERENCE LIST

1 Thermopile wire
2-4 Thermocouples
2.1, 2.2 Thermocouple legs
3.1, 3.2 Thermocouple legs
4.1, 4.2 Thermocouple legs
5 Hot connection points
6 Cold connection points
7 Thermoelectric generator
8 Winding support
9, 10 Voltage taps
11 Machine
12 Wire coating machine
13 Wire
14 Position measuring device
15 Extension device
16 Control unit
17 Winding machine
18 Thermoelectric generator
19 Winding support
20 Thermopile wire
21 Annular groove

1. A thermopile wire comprising:
a plurality of thermocouples disposed one behind another, each of said thermocouples having two thermocouple legs;
hot connection points; and
cold connection points,
wherein the thermopile wire is adapted to be wound on a winding support so that the hot connection points and the cold connection points are disposed on opposite sides of the winding support, and
wherein at least one of a length of the individual thermocouples and a length of the individual thermocouple legs increases or decreases along the thermopile wire.

2. The thermopile wire according to claim 1, wherein all directly successive thermocouples each have a given difference in length.

3. The thermopile wire according to claim 1, wherein directly successive thermocouples have a given difference in length only in the case of every n^{th} thermocouple and otherwise are of the same length.

4. The thermopile wire according to claim 2, wherein the difference in length of the directly successive thermocouples is substantially the same as a perimeter (π·d) of the thermopile wire.

5. A winding support comprising:
a) a winding region for winding with a thermopile wire, which has a plurality of thermocouples disposed one behind another and have hot connection points and cold connection points, wherein the winding region has a given winding perimeter which corresponds substantially to a length of the individual thermocouples so that the hot contact points and the cold contact points are disposed on opposite sides of the winding region in the wound state, and
b) at least one compensation region to receive at least one compensation winding of the thermopile wire, wherein the compensation region has a different winding perimeter than the winding region.

6. The winding support according to claim 5, wherein the compensation region is an annular groove which is disposed at least one end of the winding region.

7. The winding support according to claim 6, wherein the annular groove has a groove width which corresponds substantially to a diameter of the thermopile wire so that the annular groove precisely receives a winding of the thermopile wire.

8. A thermoelectric generator comprising a thermopile wire according to claim 1.

9. A method for producing a thermoelectric generator, comprising the following steps:
a) providing a thermopile wire having a plurality of thermocouples disposed one behind another and each having two thermocouple legs and hot connection points and cold connection points,
b) winding the thermopile wire on a winding support so that the hot connection points and the cold connection points lie on opposite sides of the winding support,
c) determining the actual position of at least one of the hot connection points and the cold connection points of the thermocouples in the thermopile wire,
d) determining a desired-actual deviation between the determined actual position and a given desired position, and
e) extending the thermopile wire in dependence upon the desired-actual deviation.

10. The method according to claim 12, wherein the thermopile wire is extended in such a way that the desired-actual deviation in the position of the connection points is minimized.

11. A machine for producing a thermoelectric generator, comprising:
a) a winding machine for winding a thermopile wire on a winding support, wherein the thermopile wire has a plurality of thermocouples disposed one behind the another and each having two thermocouple legs and hot connection points and cold connection points,
b) a measuring device for determining an actual position of at least one of the hot connection points and the cold connection points the individual thermocouples,
c) an extension device for variable extension of the thermopile wire in the longitudinal direction, and
d) a control unit which is connected on an input side to the measuring device and on an output side to the extension device and controls the extension device in dependence upon the determined actual position and a given desired position of at least one of the hot connection points and the cold connection points.

12. The machine as claimed in claim 11, wherein the control unit controls the extension device in such a way that a desired-actual deviation in the position of the individual connection points is minimized and the hot connection points and the cold connection points are disposed on opposite sides of the winding support.

13. The thermopile wire according to claim 1, wherein all directly successive thermocouple legs each have a given difference in length.

14. The thermopile wire according to claim 1, wherein directly successive thermocouple legs have a given difference in length only in the case of every nth thermocouple and otherwise are of the same length.

15. The thermoelectric generator according to claim 8, further comprising a winding support.

16. The method according to claim 9, wherein the thermopile wire is extended before winding.

17. The method according to claim 9, wherein the thermopile wire is extended during winding.
